(19) United States
(12) Patent Application Publication
(10) Pub. No.: US 2016/0165723 A1
(43) Pub. Date: Jun. 9, 2016

(54) CIRCUIT BOARD, PACKAGE SUBSTRATE AND ELECTRONIC DEVICE

(71) Applicant: Samsung Electro-Mechanics Co., Ltd., Suwon-si (KR)

(72) Inventors: Christian ROMERO, Suwon-si (KR); Kyung-Seob OH, Suwon-si (KR); Jeong-Ho LEE, Suwon-si (KR); Young-Do KWEON, Seoul (KR)

(73) Assignee: Samsung Electro-Mechanics Co., Ltd., Suwon-si (KR)

(21) Appl. No.: 14/955,748

(22) Filed: Dec. 1, 2015

(30) Foreign Application Priority Data
Dec. 5, 2014 (KR) 10-2014-0174245

(51) Int. Cl. H05K 1/11; H01L 23/498

(52) U.S. Cl. CPC H05K 1/113; H01L 23/49827; H01L 23/49894; H01L 23/49838

(57) ABSTRACT

A circuit board, and a package substrate and an electronic device that includes a circuit board are disclosed. The circuit board includes a core layer, a base pattern layer disposed on the core layer and a through-hole conductor that goes through the core layer, the base pattern layer including a circuit pattern that includes a conductive pad on the through-hole conductor, an insulator layer including at least one insulating layer stacked on the core layer and the base pattern layer, and a laminated pattern layer including a plurality of vias and a laminated circuit pattern, the plurality of vias penetrating the insulating layer, and the laminated circuit pattern being disposed on the insulating layer and including a plurality of via pads formed on the vias respectively.

### CROSS-REFERENCE TO RELATED APPLICATIONS

This application claims the benefit under 35 USC 119(a) of Korean Patent Application No. 10-2014-0174245 filed on Dec. 5, 2014 in the Korean Intellectual Property Office, the entire disclosure of which is incorporated herein by reference for all purposes.

### BACKGROUND

1. Field

The following description relates to a circuit board, a package substrate and an electronic device. The following description relates to, for example, a circuit board including a laminated structure of a parallel stack layer and a common via pad, and a package and an electronic device that include the same.

2. Description of Related Art

In a conventional package on package (PoP), concerns exists for electrical design flexibility in that the number of added metal layers, which may be assigned as a power distribution network (PDN), a ground sheet and/or a signal routing layer, is limited. However, one of major disadvantage of a PoP structure is high package thickness and high mechanical reliability risk due to the height of solder coupling and interface.

On the other hand, in a conventional 2.5D package, an independent silicon interposer having a through silicon via (TSV) is used as a die-to-die interconnection and mounted over a PCB or FCBGA substrate.

Both a PDN and a critical interconnection are implemented with thick metal layers in a PCB. In an active chip connecting a PDN to an internal layer through a system board, some vias are arranged for handling the requirement of much higher DC current of system. In a 2.5D packaging, a major PDN design challenge relates to an ability of very small current processing, which is not easy due to the structural limitation of TSV.

An example of a PoP is described in Published U.S. Patent Application US 2012/0158629A1 and in Published Korean Patent Application 10-2005-0065943.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a circuit board includes a core layer, a base pattern layer disposed on the core layer and a through-hole conductor that goes through the core layer, the base pattern layer including a circuit pattern that includes a conductive pad on the through-hole conductor, an insulator layer including at least one insulating layer stacked on the core layer and the base pattern layer, and a laminated pattern layer including a plurality of vias and a laminated circuit pattern, the plurality of vias penetrating the insulating layer, and the laminated circuit pattern being disposed on the insulating layer and including a plurality of via pads formed on the vias respectively, wherein at least one of the plurality of via pads is a common via pad formed over the conductor pad on the insulating layer respectively, wherein two or more of the plurality of vias are coupled to a lower part of the common via pad in parallel, wherein two or more of the plurality of vias penetrate in parallel the insulating layers so as to constitute a parallel stack layer, and wherein a portion of the parallel layer is coupled in parallel to the conductor pad.

The insulator layer may include at least two insulating layers that are laminated on each other. The number of vias of the parallel stack layer for respective layer may be the same. The vias may be vertically stacked.

The distance between composition vias of respective layer in the parallel stack layer may be equal to or less than a diameter of the through-hole conductor.

In each layer of the parallel stack layer, a center of respective composition via may be disposed within a diameter range of the through-hole conductor.

Each layer of the parallel stack layer may include a center via disposed in a lower center of the common via pad and a plurality of peripheral vias evenly placed around the center via.

The common via pad for respective layer may include at least one opening through which the insulating layer disposed below is exposed.

The at least one insulating layer may include a photosensitive material.

The at least one insulating layer may include a photosensitive material.

The circuit board may be an interposer board.

In another general aspect, a package substrate includes an interposer including the general aspect of the circuit board described above, the laminated circuit pattern of the circuit board disposed on an outer part of the interposer, and at least one chip device mounted on the interposer board and coupled to the laminated circuit pattern.

The common via pad for respective layer of the interposer board may include at least one opening through which the insulating layer disposed below is exposed.

The insulating layer and the laminated pattern layer of the interposer board may be formed over and under the core layer respectively, the parallel stack layer of the interposer board may be formed on the insulating layer formed over the core layer, and a portion of a connector of the chip device may be coupled to the common via pad among the laminated circuit pattern.

In another general aspect, an electronic device includes a general aspect of the circuit board described above.

The common via pad for respective layer of the circuit board may include at least one opening through which the insulating layer disposed below is exposed.

The circuit board may be an interposer board, the laminated circuit pattern of the circuit board disposed on an outer part of the circuit board. The electronic device may further include at least one chip device disposed on the interpose board and coupled to the laminated circuit pattern, and at least a portion of connector of the chip device may be coupled to the common via pad among the laminated circuit pattern.

The common via pad for respective layer of the interposer board may include at least one opening through which the insulating layer disposed below is exposed.

Other features and aspects will be apparent from the following detailed description, the drawings, and the claims.

### BRIEF DESCRIPTION OF THE DRAWINGS

FIG. 1 is a cross-sectional view for schematically illustrating an example of a circuit board.

FIG. 2 is a perspective view for schematically illustrating of an example of a parallel stack layer laminated on a conductive pad in a circuit board.

FIG. 3A is a perspective view for schematically illustrating of an example of a parallel stack layer laminated on a through hole and on a conductive pad in a circuit board.

FIG. 3B is a plan view for schematically illustrating an example of a parallel stack layer laminated on a conductive pad in a circuit board.

FIG. 3C is a front view for schematically illustrating an example of a parallel stack layer laminated on a through hole and on a conductive pad in a circuit board.

FIG. 4 is a cross-sectional view for schematically illustrating another example of a circuit board.

FIG. 5A is a graph for comparatively illustrating the frequency transfer characteristics of an example of a circuit board according to the present description and of a comparative example.

FIG. 5B is a graph for illustrating comparatively the route resistances of an example of a circuit board according to the present description and of a comparative example.

FIG. 6 is a cross-sectional view for schematically illustrating an example of a package substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

The terms “a,” “an,” and “the” are intended to be interpreted to include both the singular and plural forms, unless the context clearly indicates otherwise. Further, the phrase “based on” is intended to be interpreted to mean, for example, “based, at least in part, on,” unless explicitly stated otherwise. The term “and/or” is intended to be interpreted to include any and all combinations of one or more of the associated list items. The terms “comprise,” “comprises” or “comprising,” as well as synonyms thereof (e.g., include, etc.), when used in the specification, means to specify the presence of stated features, steps, or components but does not preclude the presence or addition of one or more other features, steps, components, or groups thereof. Also, the terms “couple,” “couples,” “coupled,” etc., as well as synonyms thereof (e.g., connects, linked, attached, etc.), when used in the specification, means to include a direct connection or an indirect connection between two or more elements.

The accompanying drawings in this specification are for illustrating the various embodiments, in which the shape, size, thickness and the like may be reduced or exaggerated for clarity and/or effective explanation of technical features.

A circuit board according to one aspect will be in detail explained with reference to the drawings.

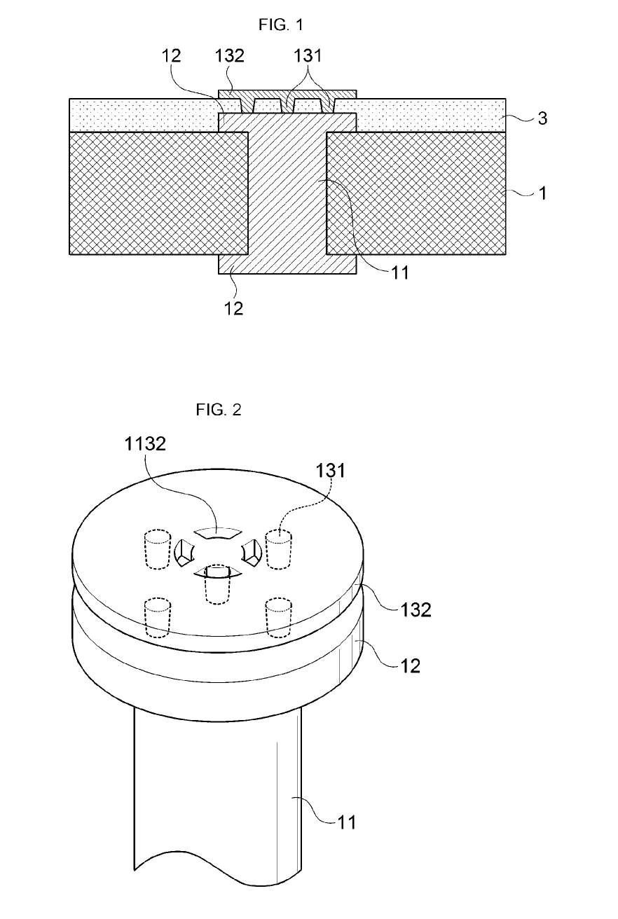

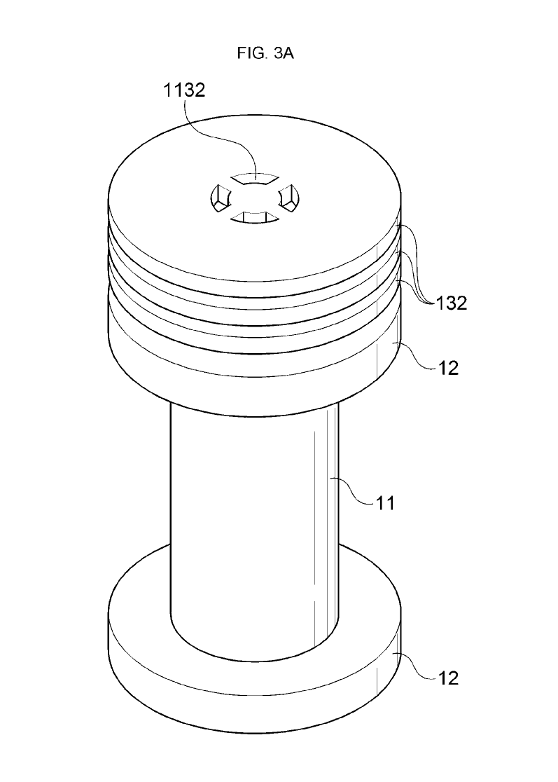

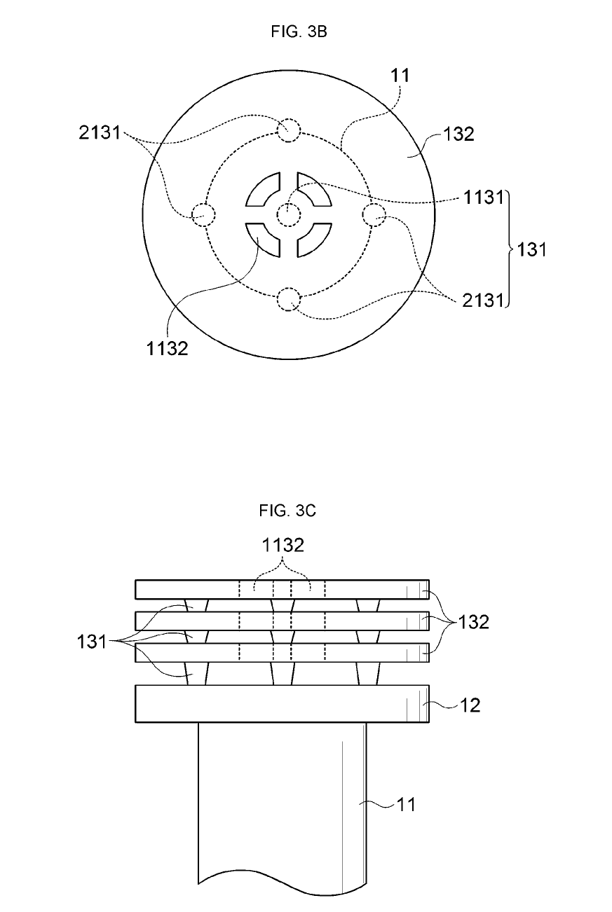

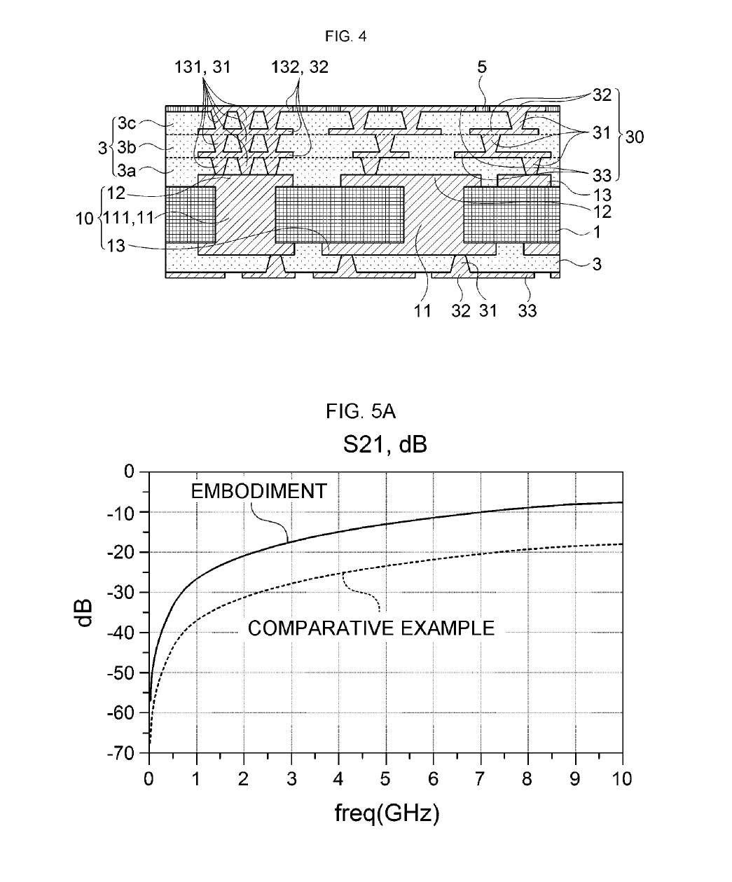

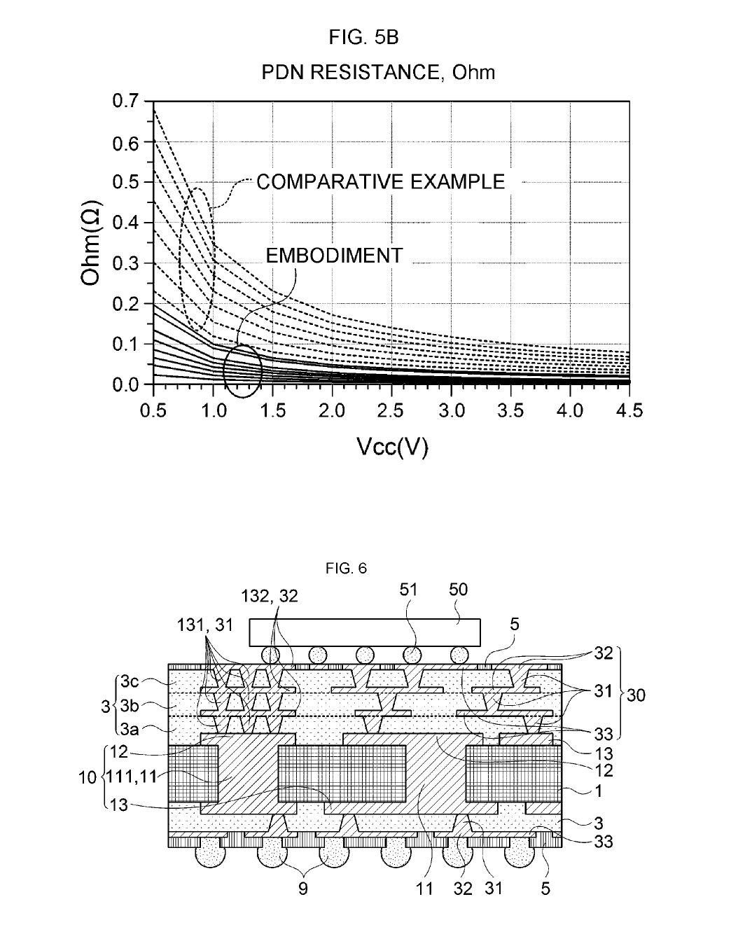

FIG. 1 illustrates a cross-sectional view of an example of a circuit board. FIG. 2 illustrates a perspective view a parallel stack layer laminated on a conductive pad according to one example of a circuit board. FIG. 3A illustrates a perspective view of a parallel stack layer laminated on a through hole and on a conductive pad according to another example of a circuit board. FIG. 3B illustrates a plan view of a parallel stack layer laminated on a conductive pad according to one example of a circuit board. FIG. 3C illustrates a front view of a parallel stack layer laminated on a through hole and on a conductive pad according to one example of a circuit board. FIG. 4 illustrates a cross-sectional view of another example of a circuit board. FIG. 5A includes a graph that illustrates the frequency transfer characteristics of an example of a circuit board according to the present description and a circuit board according to a comparative example. FIG. 5B includes a graph for illustrating the route resistances of an example of a circuit board according to the present description and a circuit board according to a comparative example.

According to one aspect, there is provided with an example of a circuit board comprising a parallel stack layer 131 on a conductive pad 12 of a through-hole conductor 11.

Though the reference numeral 131 in this specification represents a single via of parallel stack layer, it should be interpreted to represent a single via of the parallel stack layer as well as plural via(s) of the parallel stack layer(s).

For example, a circuit pattern formed over a core layer including the conductive pad 12 on which the parallel stack layer 131 is mounted, can be used as integrated power distribution network (PDN). In this example, an interposer board can be implemented to include one or more parallel stack layers 131 on the conductive pad 12 of the through-hole conductor 11. Thus, the aforementioned issue in PDN design can be solved, and the risk of peeling-off due to thermal-channeling can be reduced.

The structure of the circuit board according to one example will be explained. Referring to FIG. 1 through FIG. 4, the circuit board according to one example includes a core layer 1, a base pattern layer 10, an insulating layer 3 and a laminated pattern layer 30. Hereafter, the structure of this example is provided in detail.

The core layer 1 can serve the maintenance function of a substrate. The core layer 1 can be made of a material generally used in forming a core of a substrate. For example, the core layer 1 may be formed of a copper clad laminate (CCL), which is an insulating material having the top and the bottom thereof laminated with thin copper layers to be fabricated later with circuit pattern (corresponding to reference numerals 12 and 13) of base pattern layer 10; however, the material for the core layer 1 is not limited to this example.

In this example, an organic insulating material such as a glass or similar material can be used as the insulating material of the core layer 1. Also, the top and the bottom thin copper layers of CCL is processed so that circuit pattern (corresponding to reference numerals 12 and 13) is formed on the core layer 1.

According to one example, the circuit pattern formed on the core layer 1 may be signal transmission line, power distribution line or ground pattern. In one embodiment, the circuit patterns on the core layer 1 can be used as ground pattern or power distribution line 13 so as to form an integrated power distribution network.

Referring to FIG. 4, the base pattern layer 10 includes a through-hole conductor 11 and a circuit pattern (corresponding to reference numerals 12 and 13). The through-hole conductor 11 goes through the core layer 1. The through-hole conductor, that is a thru-hole via (THV), can be formed, by filling the through-hole formed by a perforation of the core layer 1 using a laser or the like, with a conductive metal. For example, the copper material may be used to fill the through-hole; however, the conductive metal is not limited to copper. In another example, another suitable conductive metal can be used.

Referring to FIG. 4, a circuit pattern (corresponding to reference numerals 12 and 13) is formed on the core layer 1 so as to be a base pattern layer 10. In this example, the circuit patterns 12 and 13 of the base pattern layer 10 includes a conductor pad 12 of the through-hole conductor 11. For example, the circuit pattern of the base pattern layer 10 may be composed of a conductor pad (corresponding to reference numeral 12) and a line pattern 13.

The conductor pad 12 is formed on the through-hole conductor 11 that goes through the core layer 1. The conductor pad 12 is formed over the through-hole conductor 11 and the peripheral of the core layer 1 so that the diameter of the conductor pad 12 should be greater than the diameter of the through-hole conductor 11.

For example, referring to FIG. 4, the circuit pattern of the base pattern layer 10 includes the conductor pad 12 and the line pattern 13 formed on the core layer 1. In FIG. 4, the reference numeral 12 corresponds to a conductor pad and the reference numeral 13 corresponds to a line pattern. The conductor pad 12 and the line pattern 13 may constitute a circuit pattern of the base pattern 10.

On the other hand, in FIG. 1, FIG. 2, FIG. 3A and FIG. 3C, only the conductive pad 12 is depicted as the circuit pattern of the base pattern 10; however, the present description is not limited to these examples. In another example, the circuit pattern of the base pattern layer 10 may be provided with a conductive pad 12 as well as a power distribution line and/or a ground line as line pattern.

For example, the line pattern 13 of reference numeral 13 shown in FIG. 4 may be a power distribution line and/or ground pattern 13. Thus, the parallel stack layer 131 explained later is coupled to PDN through the conductor pad 12 placed thereunder and may constitute an integrated power distribution network of the internal layer of the circuit board.

For example, referring to FIG. 4, a plurality of the through-hole conductor 11 and a plurality of the conductor pad 12 may be formed on the core layer 1. In FIG. 4, the through-hole conductor (corresponding to reference numeral 111 of FIG. 4), in which the parallel stack layer 131 explained later is formed over the plurality of through-hole conductor 11, may be at least one. That is, in case a plurality of through-hole conductor 11 are formed, the parallel stack layer 131 is formed over at least one of the through-hole conductor 11.

The circuit patterns 12 and 13 of the base pattern 10 may be formed by processing thin copper layer of CCL. In this example, the upper part and the lower part of CCL are generally 10 μm in thickness, so that the processed circuit patterns 12 and 13 can be assigned as PDN and major ground network. Also, the through-hole of CCL may be made by conventional low-cost processing such as drilling or by laser such that the diameter thereof should be greater than 80 μm (but it is not limited to this example), and the through-hole is filled with conductive material so as to be the through-hole conductor 11.

Next, referring to FIG. 1 and/or FIG. 4, the insulator layer 3 may be composed of at least one of insulating layer 3, 3a, 3b and 3c. Here, the at least one of insulating layer 3, 3a, 3b and 3c is laminated over the core layer 1 and the base pattern layer 10.

FIG. 1 shows the insulator layer 3 composed of at least one insulating layer 3 over the core layer 1, and FIG. 4 shows the conductor layer 3 composed of the insulating layers 3a, 3b and 3c which are 3-layer-laminated over the core layer 3 and the conductor 3 composed of an insulating layer 3 placed under the core layer 1, respectively.

In FIG. 1 and FIG. 4, the number of the insulating layer 3, 3a, 3b and 3c is exemplary number and it is not limited to this. In one example, at least one insulating layer 3, 3a, 3b and 3c may be made of photosensitive dielectric material. That is, the photosensitive material layers are laminated so as to be the insulator layer 3. Using a lithography processing such as UV exposure of the photosensitive insulating layer, a micro via 31 and minute pitch pattern (referring to reference numeral 33 of FIG. 4) may be formed. Using lithography processing on the photosensitive insulating layer, via 31 having diameter less than, for example, 10 μm can be formed.

In one example, the insulating layer 3, 3a, 3b and 3c is made of photosensitive dielectric material and the core layer 1 is made of CCL; the circuit pattern (corresponding to reference numerals 12 and 13 of FIG. 4) formed over the core layer 1 constitutes PDN having a wide line width and/or space and/or wide pattern such as ground pattern or the like; and in the insulating layers 3, 3a, 3b and 3c laminated over the core layer 1, the micro via 31 and minute signal line pattern 33 having narrow line width and/or space can be formed, for example, by using lithography process.

Referring to one example illustrated in FIG. 4, the insulator layer 3 is formed over and under the core layer 1, respectively. The insulator layer 3 may be up-and-down symmetric with reference to the core layer 1, or be asymmetric as shown in FIG. 4.

In the insulator layer 3, a plurality of vias 31 going through the insulating layers 3a, 3b and 3c and the circuit pattern (corresponding to the reference numerals 32 and 33 of FIG. 4) on the insulating layer are formed and may be built-up. Also, pre-buildup insulator layer 3 may be formed over the core layer 1 and the base pattern layer 10, so that the insulator layer 3 composed of a plurality of insulating layers 3a, 3b and 3c might be formed.

In this example, the parallel stack layer 131 may be formed by stacking or building-up the insulating layers 3a, 3b and 3c, or by stacking pre-buildup laminated insulating layer over the core layer 1. Next, referring to FIG. 1 and/or FIG. 4, the laminated pattern layer 30 is formed for respective insulating layer 3, 3a, 3b and 3c. In one embodiment, the laminated pattern layer 30 is formed in process of respective insulating layer, which is sequentially build-up; or is formed by stacking a pre-buildup laminated pattern layer over the core layer 1, so that the laminated pattern layer 30 should be formed in the respective insulating layer.

In FIG. 2, FIG. 3A and FIG. 3B, the core layer and the insulating layer are not shown. Instead, the through-hole conductor 11 and the conductive pad 12 are shown as base pattern layer 10, and the vias of the parallel stack layer 131 and the common via pad 132 are shown as the laminated pattern layer 30.

Referring to FIG. 1, FIG. 2, FIG. 3A, FIG. 3B, FIG. 3C and/or FIG. 4, the laminated pattern layer for respective insulating layer includes a plurality of vias 31 and laminated circuit pattern (corresponding to reference numerals 32 and 33). The plurality of vias 31 of the laminated pattern 30 penetrates through the insulating layers 3a, 3b and 3c, respectively.

In one example, in case that the respective insulating layer is made of photosensitive dielectric material, the micro via structure going through the respective insulating layer has a taper shape in cross-section view in accordance with the exposure time and the duration of lithography of the photosensitive dielectric material.

According to one embodiment, in the micro via 31 structure formed in photosensitive insulating layer, the diameter of the top thereof is greater than the diameter of the bottom thereof. In such structure, the through-hole conductor 11, that is the micro vias 31 stacked on THV has the ratio of top diameter to the bottom diameter being greater than “1”, and the diameter of so called THV is much greater than the effective diameter of the micro vias 31.

The conventional via stacking structure stacked on so called THV in line like pillar has a couple of disadvantage in electrical and mechanical design aspect. With respect to the electrical capacity, in case the stacked via connected to those having different size and/or diameter, that is in case the via is connected to the through-hole conductor 11 having large diameter, or so called THV, this structure may cause the discontinuity of impedance so as to make the high-speed signal transmission weak.

For solving this issue, one example of the circuit board comprises the laminated structure of parallel stack layer 131 and the common via pad 132. The structure of the parallel stack layer 131 and the common via pad 132 will be explained later.

Also, referring to FIG. 1 and/or FIG. 4, the laminated circuit pattern (reference numerals 32 and 33) is formed on the respective insulating layer 3, 3a, 3b and 3c.

The laminated circuit pattern (reference numerals 32 and 33) can be formed on the core layer 1 while being built-up for respective insulating layer 3, 3a, 3b and 3c, in the process of laminating of the respective insulating layer, or can be formed by stacking on the core layer 1 the laminated insulating layer which is made by pre-built up insulating layers and which includes a laminated circuit pattern (corresponding to reference numerals 32 and 33).

Referring to FIG. 4, the laminated circuit pattern (corresponding to reference numerals 32 and 33) includes a plurality of via pads 32 formed on the via 31 that goes through the respective insulating layer 3, 3a, 3b and 3c.

In FIG. 1, FIG. 2, FIG. 3A, FIG. 3B, FIG. 3C and FIG. 4, the composition via 131 of parallel stack layer is a part of via 31 that penetrates the respective insulating layer and is a part of via pad 32 formed on the respective insulating layer.

Each of the via pad 32 is formed over and around the respective via 31. Referring to FIG. 4, the laminated circuit pattern (corresponding to reference numerals 32 and 33) may include a line pattern 33 in addition to the plurality of via pads 32. In FIG. 4, the reference numeral 33 represents the line pattern 33 and reference numeral 31 represents the via pad 32. As shown in FIG. 4, the via pad 32 and the line pattern 33 may be connected.

The line pattern 33 that is a part of the laminated circuit pattern may be a line pattern for signal transmission. For example, the line pattern 33 of laminated circuit pattern may be a line pattern 33 for signal transmission, and the circuit pattern (corresponding to reference numeral 13 of FIG. 4) of base pattern 10 except the conductive pad 12 may be a line pattern for power distribution or a ground pattern 13.

In one example, in case CCL is used for the core layer 1, the circuit pattern (corresponding to the reference numeral 13 of FIG. 4) formed on the copper layer having the thickness equal to or greater than about 10 μm may be assigned to PDN and major ground pattern, while the laminated circuit pattern made by building up photosensitive insulating layers and then photo-processing such as photolithography may be assigned for high density signal routing.

The build-up process, in which the respective insulating layers 3, 3a, 3b and 3c are stacked and the laminated pattern layer 30 is formed in the respective insulation layers 3, 3a, 3b and 3c, may be performed for the core layer 1 such that the upper and the lower sides should be symmetric or asymmetric structure. In FIG. 4, though the circuit board having asymmetric structure of build-up layer is shown, the circuit board having symmetric structure of build-up layer with reference to the core layer 1 may be implemented.

Next, the laminated structure of the parallel stack layer 131 and the common via pad 132 will be explained in detail. When the laminated pattern (corresponding to reference numerals 32 and 33) of respective layer is formed, some part of the plurality of via pad 32 that constitute the laminated circuit pattern of respective layer, is the common via pad 132 formed over the conductive pad 12 in the respective insulating layers 3a, 3b and 3c.

Here, referring to FIG. 1, FIG. 2, FIG. 3B and/or FIG. 4, the common via pad 132 is a via pad formed commonly on the parallel stack layer 131 in which not only one via but a plurality of vias are stacked in parallel structure.

In other words, the parallel stack layer 131, in which a plurality of vias 31 is formed in parallel over the conductive pad 12 on the through-hole conductor 11, is formed and the common via pad 132 is formed on the parallel stack layer 131.

The diameter of the common via pad 132 is greater than the size of cluster of parallel stack layer 131 placed thereunder. For example, the size of the common via pad 132 of respective layer may be the same with the size of the conductive pad 12 within the tolerance range. The tolerance range means the error range allowed in the real manufacturing processing.

In one example, the size of the common via pad 132 of respective layer may be substantially the same with the size of the conductive pad 12. Referring to FIG. 4, in case the through-hole conductor 11 and the conductive pad 12 are formed on the core layer 1, the common pad 132 may be formed over at least one conductive pad 12.

In this example, the via 31 for general signal transmission may be formed on the conductive pad 12 over which the common via pad 132 is not formed, and a via pad 32 may be formed on the via 31.

Also, in FIG. 4, some part 131 of the plurality of via constituting the laminated circuit pattern (corresponding to reference numerals 32 and 33) may constitute the parallel stack layer 131 for respective layer.

Referring to FIG. 1 and FIG. 4, the parallel stack layer 131 is composed of vias 131 which are connected to the lower part of the common via pad 132 and which go through in parallel the insulating layers 3, 3a, 3b and 3c.

In other words, in the respective layers 3, 3a, 3b and 3c, the parallel stack layer 131, in which the plurality of vias are connected to the lower part of the common via pad 132 formed over the conductive pad 12, is formed.

The parallel stack layer 131 has the structure in which the plurality of vias 131 going through the respective insulating layers become pillar to support the common via pad 132 looking like the roof.

In this example, the parallel stack layer 131 formed on the insulating layer stacked on the core layer 1 among the parallel stack layer 131 formed under the common via pad 132 of the respective insulating layer, is connected to the conductive pad 12 in parallel.

Referring to FIG. 2 and FIG. 3B, though the number of vias constituting the respective parallel stack layer 131 is “5” in the drawings, it can be “3”, “7”, odd number higher than “7”, or even number such as “4”, “6” or the like. The number is not limited to these examples and can be proper number in accordance with the design and the pitch capability.

Referring to the example illustrated in FIG. 2, the via of the parallel stack layer 131 is formed under the common via pad 132 and is depicted in dotted line. On the other hand, in the example illustrated in FIG. 3A, the vias of the parallel stack layer under the common via pad are not shown, but can be arranged as shown in FIG. 3C.

Referring to FIG. 4, in one example, the conductor layer 3 may be formed by stacking 2 or more insulating layers. Referring to FIG. 3C and FIG. 4, the number of vias of the parallel stack layer 131 for the respective insulating layer may be the same. Here, the vias of the respective layer may be vertically stacked. According to this, the laminated structure of parallel stack layers, which forms multiple column in parallel, is formed different from the stacked via of conventional single column structure.

Here, referring to FIG. 3C and FIG. 4, in the laminated structure of the parallel stack layers, the common via pad 132 is interposed between the parallel stack layer 131 of respective layer with respect to the respective insulating layer so as to form layered structure.

In a conventional package, such as a 2.1D packaging, a flexibility exists in that the number of layer can be reduced because of the small size of line width/space and via pitch can be extended due to a high density of routing capability per layer. The major factor for the minimization and small form factor is the manufacturing capability of applying stacked micro vias having a pitch smaller than 50 μm.

However, the plurality of stacked micro vias used in a conventional packaging cause a weak signal integrity in a high speed signal transmission due to the impedance discontinuity because of the intrinsic inter-layer capacitance effect between the metal pads. The other design constraints caused by the micro vias exist in the power delivery network.

A micro via profile generally has a small diameter and a small metal volume so as to increase the DC loss and dramatically increase the current density per unit area. This may impose a risk of Joule's heating of metal interconnection that may lead to thermodynamic reliability failure.

According to one example of this present description, to solve the issues associated with using a conventional stacked micro via structure as described above, a laminated structure of parallel stack layer 131 and a common via pad 132 are provided. Thus, the current density can be reduced, and the heat dissipation can be reduced, so as to increase the thermodynamic capability.

Referring to FIG. 1, FIG. 3B, FIG. 3C and FIG. 4, according to one embodiment, the distance between the composition vias 131 in the parallel stack layer of the respective layer is equal to or less than the diameter of the through-hole conductor 11.

The distance between the composition vias is the distance between the centers of the vias, which is hereinafter called as “pitch length”. The pitch length of composition vias 131 is equal to or less than so called THV diameter, but it is not limited to this if the design capability permit. That is, if allowed in design capability, the distance between the composition vias separated with a maximum may be deviated from the diameter of the through-hole conductor 11.

Referring to FIG. 1, FIG. 3B, FIG. 3C and FIG. 4, in one embodiment, the parallel stack layer 131 for respective layer may be placed so that the center of the respective composition vias 131 should be within the diameter range of the through-hole conductor 11. In this example, the center of the composition via 131 placed in outmost of the parallel stack layer 131 of respective layer can be placed on the circle of the through-hole conductor 11.

In addition, referring to FIG. 3B, in one embodiment, the parallel stack layer 131 of respective layer may be composed of a plurality of peripheral vias 2131 which are evenly placed at and around the center via 1131 placed at the center of the lower part of the common via pad 132.

In FIG. 3B, four peripheral via 2131 are evenly placed around the center via 1131. The number of the peripheral via 2131 is 4 in the illustrated example; however, the present description is not limited to this example. The arrangement of the peripheral vias 31 is not limited to circle shape, and may be a polygon shape in another example.

Next, referring to FIG. 2, FIG. 3A and/or FIG. 3B, the circuit board according to another example will be explained. Here, the common via pad 132 of respective layer includes at least one opening 1132 which reveals the insulating layer placed thereunder.

The common via pad 132 of respective layer is a metal pad having a large size, so that parasitic capacitance might be caused between the common via pads. Here, in this embodiment, the opening 1132 may be formed on the common via pad 1132 of respective layer.

The opening 1132 is formed so that the insulating layer placed under the common via pad 132 is revealed, or the insulating layer thereunder touches the insulating layer placed over the common via pad 132 through the opening 1132.

According to this example, due to the considerably large size of the common via pad 132 in comparison to that of a conventional via pad, the parasitic capacitance of the common via pad 132 can be controlled by the size or the shape of the opening 1132, or the combination thereof.

That is, the parasitic capacitance increased in accordance with the increase of area of the common via pad 132 can be controlled by the size, the shape, or the combination thereof.

The size and/or the shape of the opening 1132 can be determined to suitable size and shape through testing various products. The shape of the opening 1132 is shown as circular arc pattern in FIG. 2 and FIG. 3A, but it is not limited to this but can be typical or atypical shapes.

In one embodiment, the opening 1132 is formed in the margin space of the composition via 131 of the parallel stack layer 131 under the common via pad 132. In one embodiment, the opening 1132 can be formed around the center via 131.

Also, the opening 1132 can be degassing passage to remove the gas trapped under the common via pad 132. In one embodiment, the opening 1132 formed around the center via 1131, such as the center micro via 31, of the parallel stack layer 131, acts as a passage to remove trapped gas caused by the material or the moisture from the manufacturing process.

Also, referring to FIG. 4, the circuit board according to another embodiment will be explained. Referring to FIG. 4, the circuit board can further comprise a solder resist layer 5 at the outermost. Here, the solder resist layer 5 protects the circuit pattern of the outermost layer and reveals the pads to be connected to a chip device of outside, or to another board using for example solder ball.

Referring to FIG. 6, the solder resist layer 5 can be covered so that the pads of the laminated circuit pattern to be connected by a first connector 51 of the chip device 50 or by a second connector 9 of itself constituting the package board should be revealed and the other patterns should be protected.

According to one embodiment, the feature of the embodiment comprising the laminated structure of the parallel stack layer 131 and the common via pad 132 will be explained in comparison with that of conventional technology.

In comparison simulation of current density, the interconnect having high current density has a low heat dissipation and has high risk in thermal reliability.

In the conventional technology in which single vias are stacked in one line, the one-line stacked structure has high current density so as to cause high heat. That is, the conventional stack via structure has a disadvantage that the current density flowing the stack via structure is so high to cause high heat and unlikely to easily dissipate the heat.

On the other hand, in the laminated structure of the parallel stack layer 131 and the common via pad 132 according to one embodiment, the current can be distributed by the plurality of vias 131 placed in parallel at respective layers so that the current density should be low, and the resistance can be reduced due to the parallel arrangement of vias 131 so as to distribute the heat.

Referring to FIG. 5A and FIG. 5B, a comparative example comprising the conventional stack via structure stacked in one line is compared with one embodiment according to the present description that comprises a laminated structure of parallel stack layer 131 and the common via pad 132.

In comparison to the example illustrated in FIG. 5A and FIG. 5B, the one embodiment has the structure of parallel stack layer 131 and the common via pad 132 as shown in FIG. 3C, and the comparative example has a via structure stacked in one line on the conductor pad.

Referring to FIG. 5A and FIG. 5B, the effect of the laminated structure of the parallel stack layer 131 and the common via pad 132 according to one embodiment of is compared with the conventional technology with respect to the resistance and the electrical performance of the signal transmission loss (s-parameter S21).

As shown in FIG. 5A, one embodiment has a superior signal transmission loss characteristics to that of the comparative example. FIG. 5B shows the route resistance, that is PDN resistance, which is function of supply voltage Vcc in accordance with the ripple frequency. In one embodiment, the resistance is lower than that of comparative example.

In design of power distribution network, DC resistance is lowered enough to adjust the IR loss. The above described circuit board according to the embodiment may be an interposer board. Referring to FIG. 6, the interposer board over which for example chip device 50 can be mounted, can be mounted on other board through the second connector 9 formed thereunder.

That is, the interposer board facilitates mounting the chip device 50 or the like. Referring to FIG. 6, the chip device 50 can be mounted on the interposer board through the first connector 51 such as micro solder ball.

In one embodiment, the interposer board includes the second connector 9 thereunder in order to be mounted to other board (not shown). Here, the second connector can be a solder ball used in BGA or the like, and can be larger in size than the first connector 51 coupling the chip device 51 and the interposer board.

In one embodiment, some part of the first connector 51 coupling the interposer board and the chip device 50 is connected to the laminated structure of the parallel stack layer 131 and the common via pad 132.

The interposer board as the circuit board according to the embodiments can be made of organic, glass or the similar material. For example, the interposer board can be made by making the core layer 1 of copper clad laminate (CCL), stacking the photosensitive insulating layer on the core layer 1, and building-up the laminated pattern layer 30.

According to the embodiment, the interposer board has the laminated structure of the parallel stack layer 131 and the common via pad 132 so as to include an integrated power distribution network (PDN) to be connected to ground pattern or power distribution line on the core layer 1.

According to one example, PDN can be implemented in the inner layer of 2.1/2.5D interposer board. In one embodiment, the laminated structure of the parallel stack layer 131 and the common via pad 132 has a capability of reducing the capacitive influence of via pads.

Also, according to one embodiment, the laminated structure of the parallel stack layer 131 and the common via pad 132 reduces the current density to reduce the heat and increase the thermodynamic performance.

Next, another example of a package substrate is described in detail. In this example, the above described circuit board according to one aspect, and FIG. 1 through FIG. 4 will be referred, and redundant description will be omitted.

FIG. 6 illustrates a cross-section view of an example of a package substrate.

Referring to FIG. 6, the package substrate includes an interposer board and at least one chip device. The package substrate can be used in an electronic device such as mobile device.

In this example, the interposer board is made of the circuit board according to one aspect. For example, the through-hole conductor 11 that penetrates the core layer of the circuit board or the interposer board may be numerous, and the number of the through-hole conductor (referred to reference numeral 111 of FIG. 6) in which the parallel stack layer 131 is formed on the conductive pad 12 on the through-hole conductor 11, can be at least one.

Referring an example illustrated in FIG. 6, the insulator layer 3 and the laminated pattern layer 30 of the interposer board or the circuit board, are formed over and under the core layer 1, respectively. Also, the parallel stack layer 131 of the circuit board or the interposer board, can be formed on the insulator layer 3 formed over the core layer 1. The explanation of the circuit board or the interposer board would be referred to the above description and would be omitted hereinafter.

Also, referring to FIG. 6, at least one chip device 50 is mounted on the interposer board, that is the circuit board. The chip device 50 is coupled to the laminated circuit pattern (referred to the reference numeral 32 and 33) formed outer part of the interposer board. In one example, the chip device can be coupled to the laminated circuit pattern through the first connector 51 thereunder.

In the example, the chip device can be a semiconductor chip as an active device, and the first connector can be a micro solder ball. Some part of the connector 51 of the chip device is coupled to the common via pad 132 among the laminated circuit pattern, that is to the laminated structure of the parallel stack layer 131 and the common via pad.

The improved semiconductor active devices require a high performance PDN having high DC current processing capability, high current capacity, and low IR loss specification, in order to control the system noise such as SSN.

In design of PDN, a number of micro vias of simple group which independently transfer the current can be used without the common via pad 132, to access other metal layers assigned to voltage supply and the ground in one layer. However, such number of vias of simple group may increase the reliability failure risk by contributing the increase of heat. On the other hand, the conventional one line stacked via structure can cause the impedance mismatch due to the diameter difference between the stack via and the through-hole conductor or due to the diameter difference between the stack vias, and can also generate a thermal channel undesired, in which the release of high heat can cause thermodynamic failure, for example, during re-flow process.

However, according to one embodiment, the laminated structure of the parallel stack layer 131 and the common via pad 132 is stacked on the conductor pad 12 formed on the through-hole conductor 11 going through the core layer 1 so as to reduce the current density and thus to reduce the heat release, which results in improvement of the thermodynamic performance.

Referring to FIG. 6, the interposer board of package substrate may further comprise a solder resist layer 5 outermost. Here, pads of the laminated circuit pattern, to which the first connector 51 of the chip device 50 is coupled, or on which the second connector 9 of the package substrate is mounted, can be revealed by the solder resist layer 5.

Also, referring to FIG. 6, in the package substrate the second connector 9 of the package substrate itself can be mounted on the outermost pads thereunder. For example, the second connector 9 of the package substrate may be bigger in size than the first connector 51 of the chip device 50. In one example, the second connector 9 may be a solder ball such as a solder ball for BGA for mounting the package substrate on another substrate (not shown).

Next, an electronic device according to another aspect will be in more detail explained. Here, the above described circuit board according to the embodiments of one aspect; the above described package substrate according to the embodiments of another aspect; and FIG. 1 through FIG. 4 and FIG. 6 will be referred, and the redundant explanation thereof will be omitted.

In one embodiment, the electronic includes a circuit board. This circuit board is the circuit board described above, according to the one aspect. The electronic device according to one embodiment may be a mobile device.

Referring to an example illustrated in FIG. 6, the insulator layer 3 and the laminated pattern layer 30 of the circuit board are formed over and under the core layer 1. The parallel stack layer 131 of the circuit board may be formed on the insulator layer 3 formed over the core layer 1.

The detailed explanation of the circuit board will be referred to the above description and will be omitted hereinafter.

Also, in one example, the circuit board may be an interposer board. The detailed explanation of the interposer board will be referred to above description. In addition, the electronic device may further comprise at least one chip device 50.

The at least one chip device 50 is coupled to the circuit board, that is the interposer board, in more detail to the laminated circuit pattern (corresponding to the reference numerals 32 and 33) formed outer part of the circuit board. In one embodiment, the chip device 50 can be coupled to the pads of the outer part of the laminated circuit pattern of the circuit board through the first connector 51 such as a micro solder ball.

Here, some part of the first connector 51 can be coupled to the common via pad 132 among the laminated circuit pattern, that is coupled to the laminated structure of the parallel stack layer 131 and the common via pad 132.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board comprising:
a core layer;
a base pattern layer disposed on said core layer and a through-hole conductor that goes through said core layer, said base pattern layer comprising a circuit pattern that comprises a conductive pad on said through-hole conductor;
an insulator layer comprising at least one insulating layer stacked on said core layer and said base pattern layer; and
a laminated pattern layer comprising a plurality of vias and a laminated circuit pattern, said plurality of vias penetrating said insulating layer, and said laminated circuit pattern being disposed on said insulating layer and comprising a plurality of via pads formed on said vias respectively,
wherein at least one of said plurality of via pads is a common via pad formed over said conductor pad on said insulating layer;
two or more of said plurality of vias are coupled to a lower part of said common via pad in parallel;
two or more of said plurality of vias penetrate in parallel said insulating layers so as to constitute a parallel stack layer; and
a portion of said parallel layer is coupled in parallel to said conductor pad.

2. The circuit board according to claim 1,
wherein said insulator layer comprises at least two insulating layers that are laminated on each other;
the number of vias of said parallel stack layer for respective layer is the same; and
said vias are vertically stacked.

3. The circuit board according to claim 1,
wherein the distance between composition vias of respective layer in said parallel stack layer is equal to or less than a diameter of said through-hole conductor.

4. The circuit board according to claim 3,
wherein, in each layer of said parallel stack layer, a center of respective composition via is disposed within a diameter range of said through-hole conductor.

5. The circuit board according to claim 3,
wherein each layer of said parallel stack layer comprises a center via disposed in a lower center of said common via pad and a plurality of peripheral vias evenly placed around said center via.

6. The circuit board according to claim 1,
wherein said common via pad for respective layer comprises at least one opening through which said insulating layer disposed below is exposed.

7. The circuit board according to claim 1,
wherein said at least one insulating layer comprises a photosensitive material.

8. The circuit board according to claim 6,
wherein said at least one insulating layer comprises a photosensitive material.

9. The circuit board according to claim 1, wherein said circuit board is an interposer board.

10. The circuit board according to claim 6, wherein said circuit board is an interposer board.

11. A package substrate comprising:
an interposer comprises said circuit board according to claim 1, said laminated circuit pattern of said circuit board disposed on an outer part of said interposer; and
at least one chip device mounted on said interposer board and coupled to said laminated circuit pattern.

12. The package substrate according to claim 11,
wherein said common via pad for respective layer of said interposer board comprises at least one opening through which said insulating layer disposed below is exposed.

13. The package substrate according to claim 11,
wherein said insulating layer and said laminated pattern layer of said interposer board are formed over and under said core layer respectively;
said parallel stack layer of said interposer board is formed on said insulating layer formed over said core layer; and
a portion of a connector of said chip device is coupled to said common via pad among said laminated circuit pattern.

14. An electronic device comprising the circuit board according to claim 1.

15. The electronic device according to claim 14,
wherein said common via pad for respective layer of said circuit board comprises at least one opening through which said insulating layer disposed below is exposed.

16. The electronic device according to claim 14,
wherein said circuit board is an interposer board, said laminated circuit pattern of said circuit board disposed on an outer part of said circuit board;
said electronic device further comprises at least one chip device disposed on said interpose board and coupled to said laminated circuit pattern; and
at least a portion of connector of said chip device is coupled to said common via pad among said laminated circuit pattern.

17. The electronic device according to claim 16,
wherein said common via pad for respective layer of said interposer board comprises at least one opening through which said insulating layer disposed below is exposed.
